(19) United States
(12) Patent Application Publication
(10) Pub. No.: US 2023/0097273 A1
(43) Pub. Date: Mar. 30, 2023

(54) Method and Drill for Removing Partial Metal Wall of Hole

(71) Applicant: Unimicron Technology Corporation, Taoyuan City (TW)

(72) Inventor: Cheng-Jui Chang, Taoyuan City (TW)

(21) Appl. No.: 17/508,421

(22) Filed: Oct. 22, 2021

(30) Foreign Application Priority Data
Sep. 29, 2021 (TW) 110136196

(51) Int. Cl. H05K 3/00; H05K 3/04

(52) U.S. Cl. CPC H05K 3/0047; H05K 3/04; H05K 2203/0207

(57) ABSTRACT

The method for removing partial metal wall of hole of the present invention includes the following steps. First, a circuit board is provided. The circuit board includes a plurality of circuit layers, a plurality of dielectric layers, and a plated through hole. Each of the dielectric layers is between two adjacent circuit layers. The wall of the plated through hole includes at least one residual copper. The circuit layer immediately below the residual copper is defined as a signal layer. Next, a position of the signal layer and a position of the residual copper in the plated through hole are obtained. Next, a drill is provided, the drill includes a main body and at least one needle, and the drill is moved to the position of the residual copper. The main body is rotated around the central axis of the main body, so the needle can remove part of the residual copper.

### FIELD OF THE DISCLOSURE

The present invention relates to a technical field of processing printed circuit boards, and more particularly to a method and drill for removing partial metal wall of hole.

### BACKGROUND OF THE INVENTION

Please refer to FIG. 1. In the printed circuit board 8, there is often residual copper 80R remaining on the wall of the plated through hole 80. The residual copper 80R will affect the signal transmission and cause the reflection of the transmitted signal, resulting in noise and distortion of the signal. The bad effect of the residual copper 80R on high-frequency communication is obvious and called the stub effect.

The current method for removing the stub effect is to use a drill whose needle diameter is larger than the inner diameter of the plated through hole 80 and to remove the residual copper by drilling a certain depth. However, there are still some disadvantages in the current method. For example:
1. The drilling area is relatively large. Therefore, much extra space should be reserved on the printed circuit board 8 at the design stage.
2. The drilling depth is usually deeper and much material of the printed circuit board 8 is removed in the drilling, increasing the defect rate in the manufacturing process of the printed circuit board 8.
3. The tolerance of the drilling depth is too large to be well controlled. Therefore, the quality of eliminating the stub effect is unstable.

Therefore, how to improve the quality of eliminating the stub effect is worth considering for person having ordinary skill in the art.

### SUMMARY OF THE INVENTION

The objective of the present invention is to provide a method for removing partial metal wall of hole. The method can improve the quality of eliminating the stub effect and reduce the damage to the printed circuit board.

The method for removing partial metal wall of hole in the present invention includes following steps.

First, a circuit board is provided. The circuit board includes a plurality of circuit layers, a plurality of dielectric layers and a plated through hole. Each of the dielectric layers is between two adjacent circuit layers. A wall of the plated through hole includes at least one residual copper. The circuit layer immediately below the residual copper is defined as a signal layer. Next, a position of the signal layer and a position of the residual copper in the plated through hole is obtained by measurement. Next, a drill is provided. The drill includes a main body and at least one needle and is moved to the position of the residual copper above the signal layer. The main body is rotated around the central axis of the main body so that the needle removes part of the residual copper.

In the method for removing partial metal wall of hole, there is an angle between the central axis of the main body and the central axis of the needle.

In the method for removing partial metal wall of hole, the angle is 90°.

In the method for removing partial metal wall of hole, the width of the drill is larger than the radius of the plated through hole.

In the method for removing partial metal wall of hole, the width of the drill is less than or equal to the radius of the plated through hole.

In the method for removing partial metal wall of hole, a preliminary through hole is defined as the plated through hole that has not been plated, and when the main body is rotated, the main body also is moved in a horizontal circular path. The radius of the horizontal circular path plus the width of the drill is larger than the radius of the preliminary through hole.

In the method for removing partial metal wall of hole, a preliminary through hole is defined as the plated through hole that has not been plated, and when the main body is rotated, the main body also is simultaneously moved in a horizontal circular path. The radius of the horizontal circular path plus the width of the drill is larger than the radius of the preliminary through hole.

Another objective of the present invention is to provide a drill for removing a partial metal wall of hole. The drill can improve the quality of eliminating the stub effect and reduce the damage to the printed circuit board.

A drill for removing partial metal wall of hole is used to a circuit board. The circuit board includes a plurality of circuit layers, a plurality of dielectric layers and a plated through hole. Each of the dielectric layers is between two adjacent circuit layers. A wall of the plated through hole includes at least one residual copper. The position of the residual copper is corresponding to the position of one or more of the dielectric layers. The drill includes a main body and at least one needle. There is an angle between the central axis of the main body and the central axis of the needle. The needle is used to remove part of the residual copper.

In the drill for removing partial metal wall of hole, the angle is 90°.

In the drill for removing partial metal wall of hole, the width of the drill is larger than the radius of the plated through hole.

In the drill for removing partial metal wall of hole, the width of the drill is less than or equal to the radius of the plated through hole.

The present invention has the following advantages: the method and the drill for removing partial metal wall of hole can improve the quality of eliminating the stub effect and reduce the damage to the printed circuit board. The parasitic capacitance effect caused by the stub effect on the through hole is also eliminated, such as the problem of signal distortion caused by noise. And the method can ensure the normal conduction of other inner-layer circuits.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 illustrates a schematic view of an residual copper remaining on a wall of a plated through hole 80;

FIG. 2 illustrates a flow chart of a method for removing a partial metal wall of hole of the present invention;

FIG. 3A illustrates a schematic view of a circuit board 9;

FIG. 3B illustrates a schematic view of a preliminary through hole 90′;

FIG. 4A and FIG. 4B illustrates a schematic view of a sensing component 60 inserted into a plated through hole 90;

FIG. 4C illustrates a schematic view of a capacitance sensing curve;

FIG. 5A illustrates a schematic view of a drill 7;

FIG. 5B illustrates a schematic view of the needle 71 moved to an residual copper 90R;

FIG. 5C illustrates a schematic view of drill 7 in other embodiment;

FIG. 6 illustrates a schematic view of the needle 71 drilling part of the residual copper 90R and part of a dielectric layer 92; and

FIG. 7 illustrates a schematic view of the needle 71′ drilling part of the residual copper 90R and part of a dielectric layer 92.

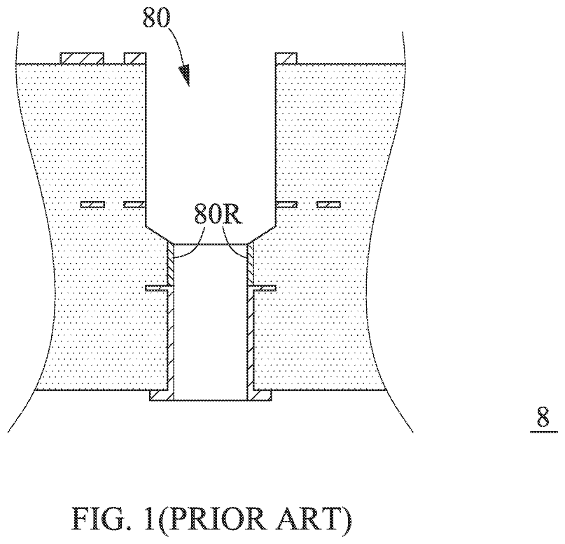

### DESCRIPTION OF THE PREFERRED EMBODIMENTS

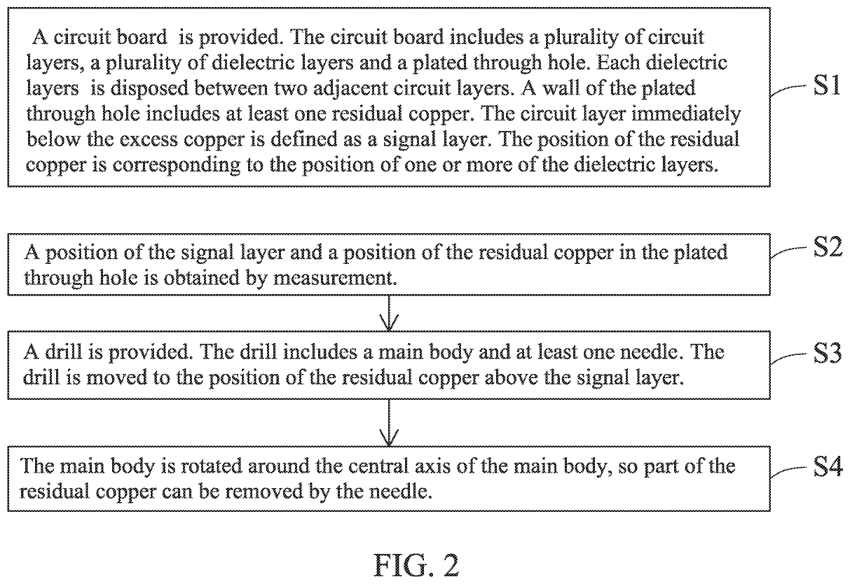

Please refer to FIG. 2. FIG. 2 illustrates a flow chart of a method for removing a partial metal wall of hole of the present invention. The method for removing partial metal wall of hole includes following steps.

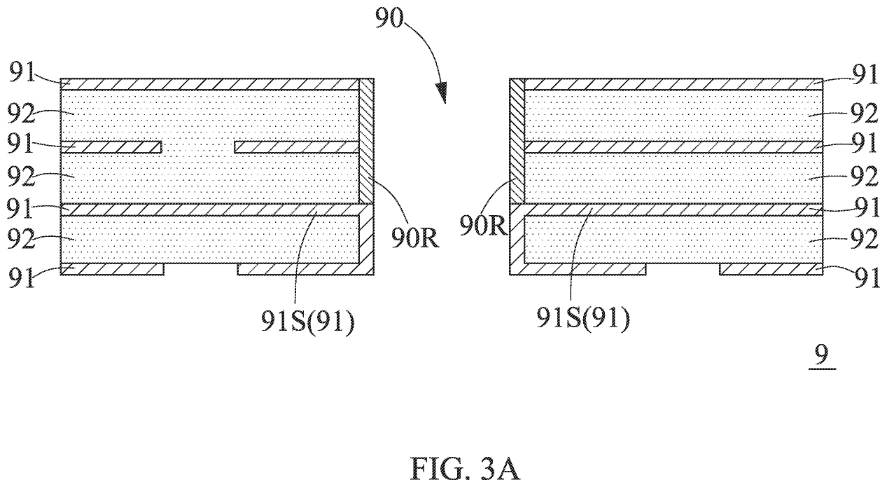

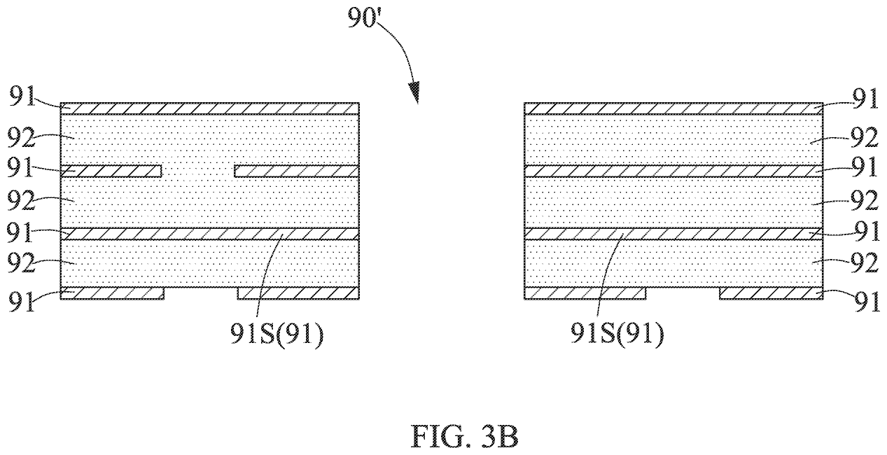

First, please refer to the step S1 and FIG. 3A. A circuit board 9 is provided. The circuit board 9 includes a plurality of circuit layers 91, a plurality of dielectric layers 92 (FIG. 3A shows a three-layer dielectric layer 92) and a plated through hole 90. Each dielectric layer 92 is disposed between two adjacent circuit layers 91. A wall of the plated through hole 90 includes at least one residual copper 90R. The circuit layer 91 immediately below the residual copper 90R is defined as a signal layer 91S. The position of the residual copper 90R is corresponding to the position of one or more of the dielectric layers 92. In the embodiment, the position of the residual copper 90R is corresponding to the positions of the first and second layers of the dielectric layers 92 from top to bottom.

Please refer to FIG. 3B. FIG. 3B illustrates a schematic view of a preliminary through hole 90′. A preliminary through hole 90′ is defined as the plated through hole 90 that has not been plated. In the embodiment, the radius of the preliminary through hole 90′ is equivalent to the radius of the plated through hole 90 plus the thickness of the residual copper 90R.

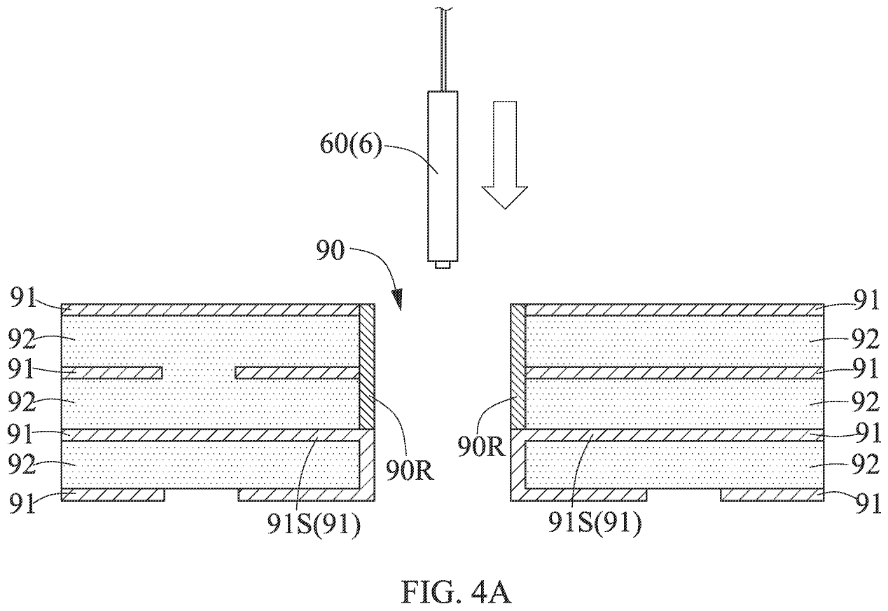

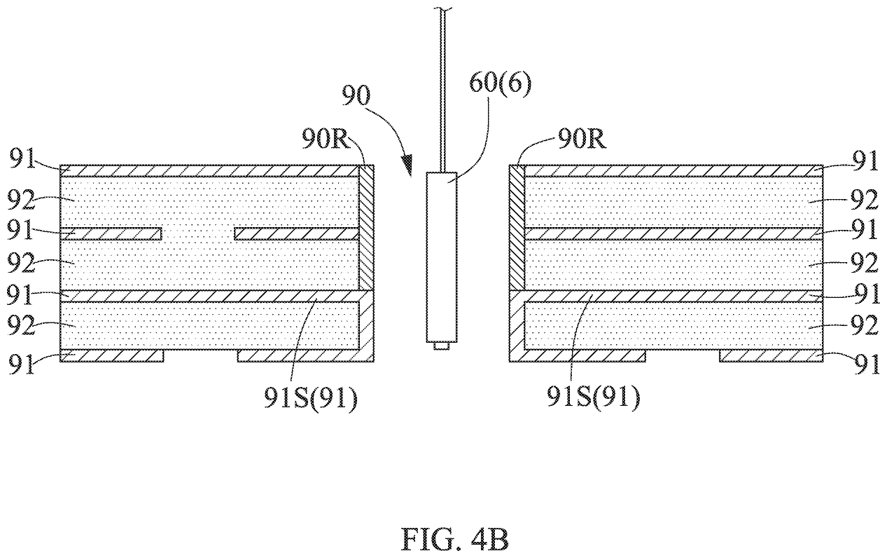

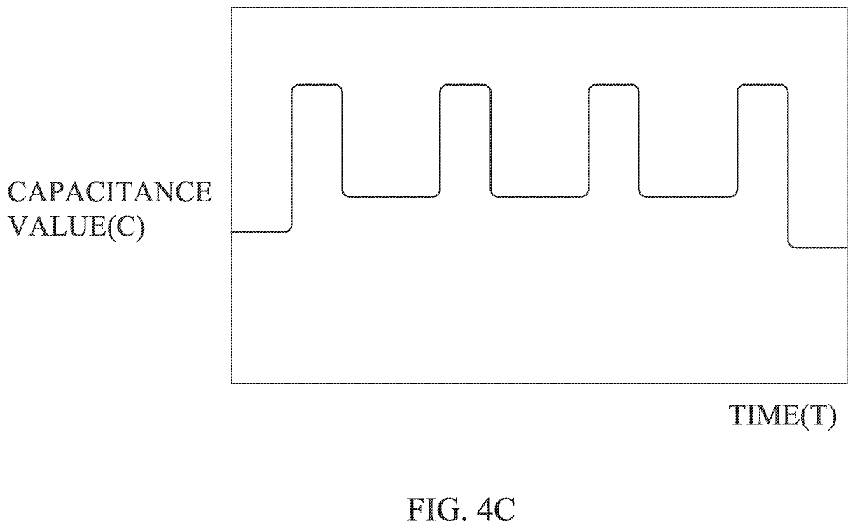

Please refer to the step S2, FIG. 4A, FIG. 4B and FIG. 4C. A position of the signal layer 91S in the plated through hole 90 is obtained by measurement. Specifically, in the embodiment, a capacitance sensing device 6 is configured to detect the change of the capacitance value in the plated through hole 90. The capacitance sensing device 6 includes a sensing component 60. The sensing component 60 is configured to enter the plated through hole 90 and move along the plated through hole 90 to sense the change of the capacitance value in the plated through hole 90 to generate a capacitance sensing curve (please refer to FIG. 4C). In the capacitance sensing curve, the number of the fluctuations in the capacitance value is equivalent to the number of the circuit layer 91 passed by the sensing component 60. In addition, after measuring the width of the valley of the capacitance sensing curve (i.e., the required time (t)) and considering the moving speed (v) of the sensing component 60, the thickness of the dielectric layer 92 (d, d=v×t) can be calculated. Therefore, the position of the signal layer 91S can be obtained by the number of layers passed by the sensing component 60 and the thickness of each of the dielectric layers 92. By obtaining the position of the signal layer 91S, the position of the residual copper 90R can be obtained at the same time.

In the above embodiment, the position of the signal layer 91S is obtained by detecting the change of the capacitance value in the plated through hole 90. However, in other embodiments, an inductive sensing device can also be used to detect the change of the inductance value in the through hole, and thus the position of the signal layer 91S can also be obtained. Moreover, in addition to detecting the change of the capacitance value or the inductance value, the operator can also put a lens module into the plated through hole 90 to directly photograph the wall to obtain the position of the signal layer 91S. The embodiment for obtaining the position of the signal layer 91S in the present invention is not limited to these abovementioned methods.

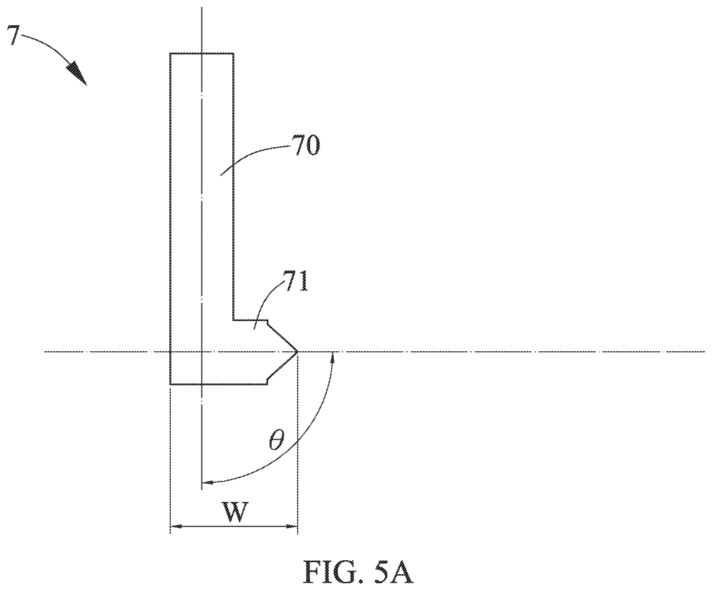

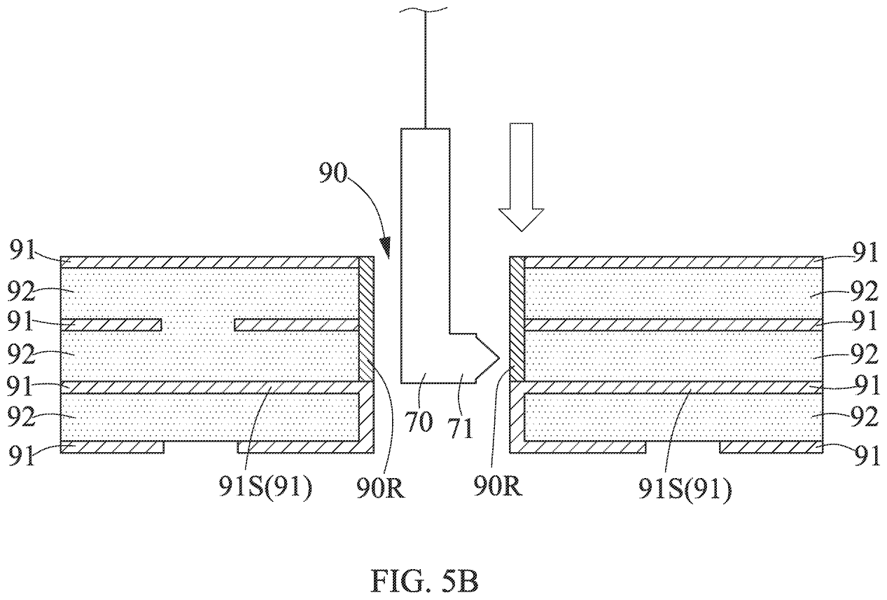

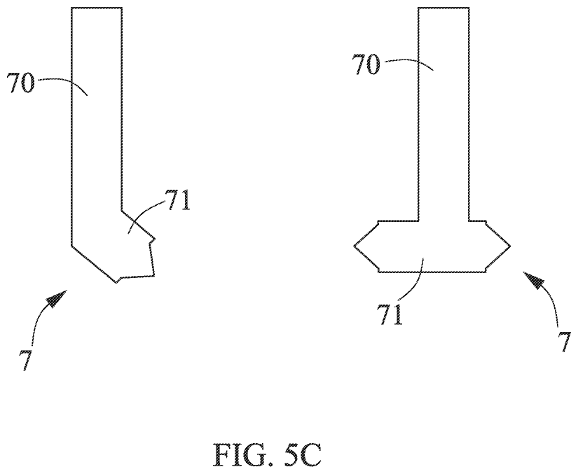

Please refer to the step S3, FIG. 5A and FIG. 5B. A drill 7 is provided. The drill 7 includes a main body 70 and at least one needle 71. The drill 7 is moved to the position of the residual copper 90R above the signal layer. The main body 70 is rotated around the central axis of the main body 70 so that the needle 71 removes part of the residual copper 90R. The drill 7 is moved to an appropriate position of the residual copper 90R above the signal layer 91S. The appropriate position is determined by the tolerance of the positioning of the drilling device. There is an angle θ between the central axes of the main body 70 and the needle 71. The preferred angle θ is 90°, which is conducive to the subsequent drilling and removal of the residual copper 90R. Besides, the combined range of the main body 70 and the needle 71 is equivalent to the width W of the drill 7. In the embodiment, the width W of the drill 7 is larger than the radius of the plated through hole 90. Thus, the central axis of the main body 70 needs to be deviated from the center position of the plated through hole 90 in order to move the drill 7 into the plated through hole 90 without touching the plated through hole 90. Next, please refer to FIG. 5B. The needle 71 is moved to the position of the residual copper 90R according to the measurement result of the step S2.

Please refer to FIG. 5C. FIG. 5C illustrates a schematic view of drill 7 in other embodiments. In the embodiment, the shape of the drill 7 is L-shaped. However, the shape of the drill 7 can also be J-shaped or T-shaped, as long as the projection of the diameter of the needle 71 in the horizontal direction is larger than the diameter of the main body 70.

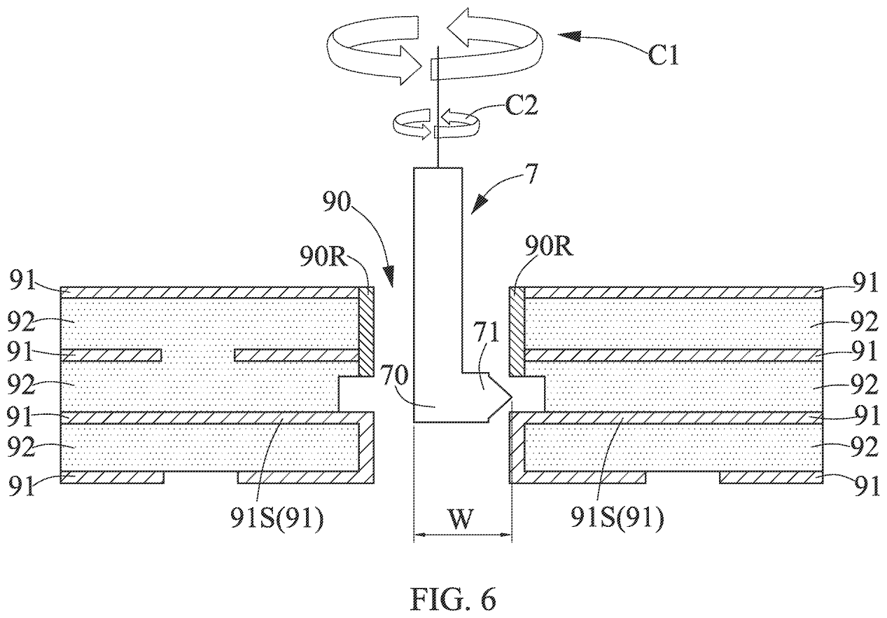

Please refer to the step S4, FIG. 6 and FIG. 3B. The main body 70 is rotated around the central axis of the main body 70, that is, when the main body 70 performs a rotation C2, the main body 70 is also moved in a horizontal circular path C1. The radius of the horizontal circular path C1 plus the width of the drill 7 is larger than the radius of the preliminary through hole 90′, so part of the residual copper 90R can be removed by the needle 71.

In detail, the width W of the drill 7 is larger than the radius of the plated through hole 90. Therefore, after the central axis of the main body 70 of the drill 7 is moved transversely to the center position of the plated through hole 90, the needle 71 can touch the residual copper 90R. Next, the drill needle 7 performs the rotation C2 around the central axis of the main body 70 and a movement along the horizontal circular path C1, so part of the residual copper 90R can be removed. In the process of removing part of the residual copper 90R, a small part of the dielectric layer 92 may also be removed. However, in contrast to the prior art, the method for removing the stub effect in the embodiment has greatly reduced the loss of material of the printed circuit board. Therefore, in contrast to the current method for removing the stub effect, the method for removing partial metal wall of hole specifically removes the residual copper 90R, so the quality of eliminating the stub effect is improved. In addition, the damage to the circuit board 9 and the defect rate of the circuit board 9 are also reduced, and at the design stage less extra space of the circuit board 9 is required.

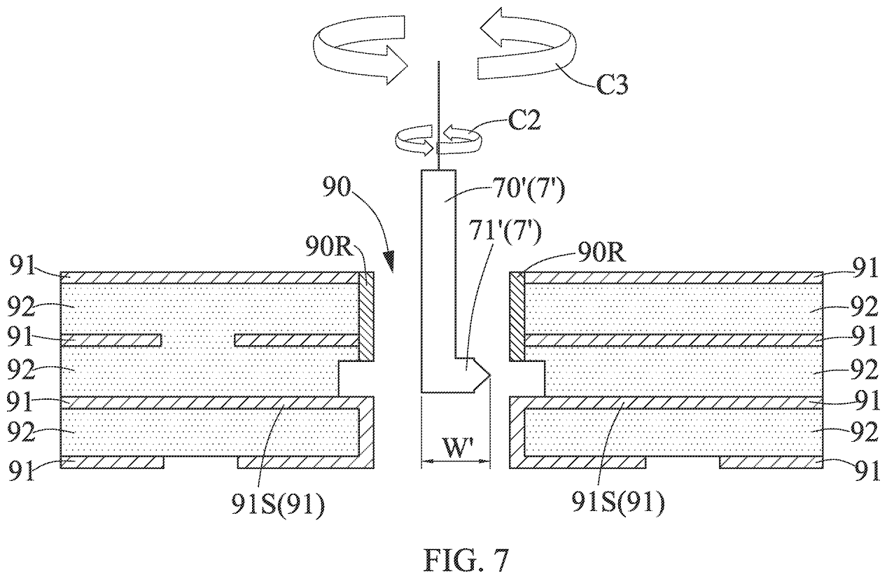

Please refer to FIG. 7. In other embodiments, the width W′ of the drill 7′ may not be larger than the radius of the plated through hole 90. Therefore, the main body 70′ of the drill 7′ can enter the plated through hole 90 along the central axis of the plated through hole 90. However, because the width W′ of the drill 7′ is not larger than the radius of the plated through hole 90, the needle 71′ cannot touch the residual copper 90R if the central axis of the main body 70′ is aligned with that of the plated through hole 90. Thus, when the main body 70′ is in the plated through hole 90, the rotation C2 and a movement along a horizontal circular path C3 need to be performed at the same time. Please be noted, the horizontal circular path C3 in FIG. 7 is larger than the horizontal circular path C1 in FIG. 6. The radius of the horizontal circular path C3 plus the width W′ of the drill 7′ is larger than the radius of the preliminary through hole 90′. As a result, the needle 71′ can remove part of the residual copper 90R.

In other embodiments, the drill 7 can also be directly connected to the capacitance sensing device 6. Thus, the drill 7 is equivalent to the sensing component 60 in the step S2. The needle 71 directly contacts the copper of the plated through hole 90 and enters the plated through hole 90 along the wall to sense the fluctuation of the capacitance value. In the embodiment, when the drill 7 senses the third fluctuation change, it stops going down, which means that the needle 71 has reached the adjacent layer of the signal layer 91S. Next, the needle 71 is raised an appropriate distance, and the needle 71 can reach the position of the residual copper 90R and removes part of the residual copper 90R directly.

In summary, the method and the drill for removing partial metal wall of hole of the present invention can improve the quality of eliminating the stub effect and reduce the damage to the printed circuit board.

Although the description above contains many specifics, these are merely provided to illustrate the invention and should not be construed as limitations of the invention's scope. Thus, it will be apparent to those skilled, in the art that various modifications and variations can be made in the system and processes of the present disclosure without departing from the spirit or scope of the invention.

What is claimed is:

1. A method for removing partial metal wall of hole, comprising:
providing a circuit board including a plurality of circuit layers, a plurality of dielectric layers and a plated through hole, the dielectric layer disposed between two adjacent circuit layers, a wall of the plated through hole including at least one residual copper, and the circuit layer immediately below the residual copper defined as a signal layer;
obtaining a position of the signal layer and a position of the residual copper in the plated through hole by measurement;
providing a drill including a main body and at least one needle and moving the drill to the position of the residual copper; and
rotating the main body around a central axis of the main body to make the needle remove part of the residual copper.

2. The method for removing partial metal wall of hole according to claim 1, wherein there is an angle between the central axis of the main body and the central axis of the needle.

3. The method for removing partial metal wall of hole according to claim 2, wherein the angle is 90°.

4. The method for removing partial metal wall of hole according to claim 3, wherein the width of the drill is larger than the radius of the plated through hole.

5. The method for removing partial metal wall of hole according to claim 3, wherein the width of the drill is less than or equal to the radius of the plated through hole.

6. The method for removing partial metal wall of hole according to claim 4, wherein a preliminary through hole is defined as the plated through hole that has not been plated, and when the main body is rotated, the main body also is moved in a horizontal circular path, and the radius of the horizontal circular path plus the width of the drill is larger than the radius of the preliminary through hole.

7. The method for removing partial metal wall of hole according to claim 5, wherein a preliminary through hole is defined as the plated through hole that has not been plated, and when the main body is rotated, the main body also is simultaneously moved in a horizontal circular path, and the radius of the horizontal circular path plus the width of the drill is larger than the radius of the preliminary through hole.

8. A drill for removing partial metal wall of hole used to a circuit board, the circuit board including a plurality of circuit layers, a plurality of dielectric layers and a plated through hole, each dielectric layer disposed between two adjacent circuit layers, a wall of the plated through hole including at least one residual copper, and the position of the residual copper corresponding to the position of one or more of the dielectric layers, the drill comprising:
a main body; and
at least one needle, having an angle between the central axis of the main body and the central axis of the needle;
wherein the needle is used to remove part of the residual copper.

9. The drill for removing partial metal wall of hole according to claim 8, wherein the angle is 90°.

10. The drill for removing partial metal wall of hole according to claim 9, wherein the width of the drill is larger than the radius of the plated through hole.

11. The drill for removing partial metal wall of hole according to claim 9, wherein the width of the drill is less than or equal to the radius of the plated through hole.
